(19) United States
(12) Patent Application Publication
(10) Pub. No.: US 2018/0196272 A1
(43) Pub. Date: Jul. 12, 2018

(54) 3D DISPLAY DEVICE

(71) Applicant: Shenzhen China Star Optoelectronics Technology Co., Ltd., Shenzhen City (CN)

(72) Inventor: Lixuan Chen, Shenzhen City (CN)

(21) Appl. No.: 15/116,220

(22) PCT Filed: Jul. 15, 2016
(86) PCT No.: PCT/CN2016/090117

§ 371 Date: Aug. 3, 2016

(30) Foreign Application Priority Data
Jun. 22, 2016 (CN) 201610454894.0

(51) Int. Cl. G02B 27/22; H01L 25/075; H01L 33/56; H01L 33/58; H01L 33/62; H01L 33/30; H01L 33/32

(52) U.S. Cl. CPC G02B 27/2214; H01L 25/0753; H01L 33/56; H01L 33/32; H01L 33/62; H01L 33/30; H01L 33/58

(57) ABSTRACT

The invention provides a 3D display device, which uses micro LEDs display device to display image and disposes a microlens encapsulating array layer (4) at the light-emitting side of the micro LED display device. The microlens encapsulating array layer (4) provides both encapsulating protection to the micro LEDs (2) and distinguishing the left-eye and right-eye viewpoints to achieve 3D display. With the microlens encapsulating array layer (4), the structure of the micro LED 3D display device is simplified to achieve naked-eye 3D display, reduce production cost and improve display quality.

### BACKGROUND OF THE INVENTION

### 1. Field of the Invention

The present invention relates to the field of display, and in particular to a three-dimensional (3D) display panel

### 2. The Related Arts

The panel display device, due to the advantages of high display quality, low power-consumption, thin size and wide application, is widely used in mobile phones, TV, PDA, digital camera, notebook PC, desktop PC, and so on, and becomes the mainstream technology.

The micro light-emitting diode (micro LED, μLED) display device is a display device which utilizes high density micro-scaled LED array integrated on a substrate as display pixels to achieve image display. Similar to a larger-scaled outdoor LED display, each pixel is addressable and individually driven to emit light, and can be viewed as a reduce-sized outdoor LED display by reducing the inter-pixel distance from cm scale to mm scale. Micro LED display device and the organic light-emitting diode (OLED) are both self-luminous, but the micro LED shows the advantages of higher material stability, longer lifespan and no image imprinting as compared to the OLED, and is considered as the major competing technology for OLED display device.

The micro transfer printing (MTP) is the mainstream technology to manufacture micro LED display device. Specifically, first, the micro LED element is grown on the sapphire-based substrate; a laser lift-off (LLO) technology is used to separate the micro LED bare chip from the sapphire-based substrate, and then a patterned polydimethylsiloxane (PDMS) transfer stamp is used to adsorb to the micro LED bare chip off from the sapphire-based substrate; the PDMS transfer stamp is aligned with the receiving substrate for positioning; and then the micro LED bare chip adsorbed by the PDMS transfer stamp is attached to the pre-set position on the receiving substrate; and then the PDMS transfer stamp is peeled off to accomplish micro LED bare chip transfer to further manufacture the micro LED display device. It should be noted that after MTP, the micro LED bare chip is exposed on the receiving substrate. To seal and protect the micro LED bare chip from the humidity, further encapsulation must be performed on the micro LED bare chip. In general, a layer of organic polymer is coated over the micro LED bare chip to achieve the encapsulation protection of the micro LED bare chip.

The three-dimensional (3D) display device based on microlens array is a 3D display device without the need of any auxiliary viewing device, which usually comprises: a two-dimensional (2D) display panel, and a microlens array disposed at the light-emitting side of the 2D display panel; wherein the 2D display panel providing a plurality of stereoscopic parallax images from the same scene, the microlens array using light refraction to separate these parallax images in spatial directions to form different viewpoints. When the eyes of the viewer are in different viewpoints, the user can view the corresponding parallax images to achieve 3D viewing.

### SUMMARY OF THE INVENTION

The object of the present invention is to provide a 3D display panel, able to simplify the structure of the micro LED 3D display device to achieve naked-eye 3D display and reduce manufacturing cost.

To achieve the above object, the present invention provides a 3D display device, which comprises: a substrate, a plurality of micro LEDs disposed on the substrate and arranged in an array, a dielectric layer disposed on the plurality of micro LEDs, and a microlens encapsulating array layer disposed on the dielectric layer; the dielectric layer being made of a transparent dielectric; the microlens encapsulating array layer encapsulating and protecting the micro LEDs, and refracting light emitted by the micro LEDs at different locations of the substrate to different spatial directions to form a left-eye viewpoint and a right-eye viewpoint for a viewer so as to achieve 3D display.

The microlens encapsulating array layer is made of semiconductor material, ammonium dichromate gelatin, or resin-based material.

The microlens encapsulating array layer is prepared by a photo-resist melting method.

The microlens encapsulating array layer comprises: a plurality of microlens units arranged in an array, and the microlens unit has a hemispherical shape.

The plurality of micro LEDs comprises: red micro LEDs, green micro LEDs and blue micro LEDs.

The plurality of micro LEDs is manufactured by micro transfer printing (MTP).

A control circuit connected to the plurality of micro LEDs is disposed between the substrate and the plurality of micro LEDs.

The plurality of micro LEDs is GaN micro LEDs, InGaN micro LEDs, or AlGaInP micro LEDs.

The present invention also provides a 3D display device, which comprises: a substrate, a plurality of micro LEDs disposed on the substrate and arranged in an array, a dielectric layer disposed on the plurality of micro LEDs, and a microlens encapsulating array layer disposed on the dielectric layer; the dielectric layer being made of a transparent dielectric; the microlens encapsulating array layer encapsulating and protecting the micro LEDs, and refracting light emitted by the micro LEDs at different locations of the substrate to different spatial directions to form a left-eye viewpoint and a right-eye viewpoint for a viewer so as to achieve 3D display; wherein the microlens encapsulating array layer being made of semiconductor material, ammonium dichromate gelatin, or resin-based material; and the microlens encapsulating array layer being prepared by a photo resist melting method.

Compared to the known techniques, the present invention provides the following advantages: the present invention provides a 3D display device, which uses micro LEDs display device to display image and disposes a microlens encapsulating array layer at the light-emitting side of the micro LED display device. The microlens encapsulating array layer provides both encapsulating protection to the micro LEDs and distinguishing the left-eye and right-eye viewpoints to achieve 3D display. With the microlens encapsulating array layer, the structure of the micro LED 3D display device is simplified to achieve naked-eye 3D display, reduce production cost and improve display quality.

### BRIEF DESCRIPTION OF THE DRAWINGS

To make the technical solution of the embodiments according to the present invention, a brief description of the drawings that are necessary for the illustration of the embodiments will be given as follows. Apparently, the drawings described below show only example embodiments of the present invention and for those having ordinary skills in the art, other drawings may be easily obtained from these drawings without paying any creative effort. In the drawings:

FIG. 1 is a schematic view showing the structure of 3D display device provided by a first embodiment of the present invention;

### DETAILED DESCRIPTION OF THE PREFERRED EMBODIMENTS

To further explain the technical means and effect of the present invention, the following refers to embodiments and drawings for detailed description.

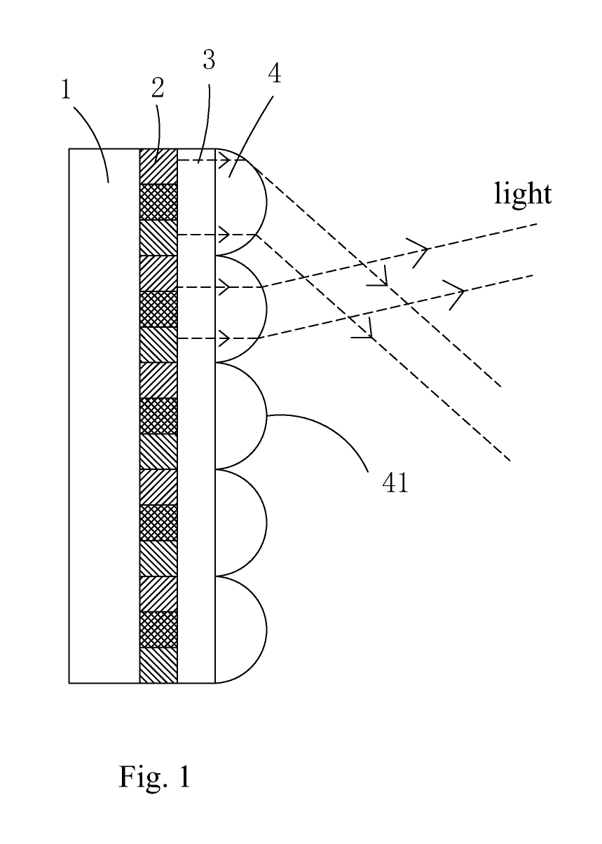

Refer to FIG. 1. The present invention provides a 3D display device, which comprises: a substrate 1, a plurality of micro LEDs 2 disposed on the substrate 1 and arranged in an array, a dielectric layer 3 disposed on the plurality of micro LEDs 2, and a microlens encapsulating array layer 4 disposed on the dielectric layer 3.

Specifically, the dielectric layer 3 is made of a transparent dielectric, with a certain thickness so that the microlens encapsulating array layer 4 can perform spectral on the light emitted by the micro LEDs 2 to achieve 3D display.

It should be noted that the microlens encapsulating array layer 4 must perform two functions. First, the microlens encapsulating array layer 4 encapsulates and protects the micro LEDs 2 to prevent humidity damaging the micro LEDs 2 to prolong the lifespan of the micro LEDs 2. Second, the microlens encapsulating array layer 4 is to achieve 3D display. By refracting light emitted by the micro LEDs 2 at different locations of the substrate 1 to different spatial directions to form a left-eye viewpoint and a right-eye viewpoint for a viewer, the microlens encapsulating array layer 4 achieves 3D display. Moreover, the left eye and the right eye of the viewer receive respectively different parallax images of the same scene displayed by the micro LEDs located at different locations on the substrate 1, and the visual center fuses the images to obtain the 3D perspective.

Specifically, the microlens encapsulating array layer 4 can be made of semiconductor material, such as InP, or, ammonium dichromate gelatin, or resin-based material. The microlens encapsulating array layer 4 comprises: a plurality of microlens units 41 arranged in an array, and the microlens unit 41 preferably has a hemispherical shape.

Specifically, the microlens encapsulating array layer 4 is prepared by a photo-resist melting method. The specific process comprises: first, coating a photo-resist layer on a substrate of a certain thickness, subsequently exposing and developing the photo-resist layer to form a photo-resist layer having a cylinder array pattern, and then heating the photo-resist layer a molten state, so that the surface tension of the cylindrical structure transforms the cylinder into a smooth hemispheric structure, and finally transferring the photo-resist microlens pattern to another carrier by reactive ion etching to obtain a microlens array.

It should be noted that the plurality of micro LEDs 2 is manufactured by micro transfer printing (MTP). Specifically, the process comprises: growing a plurality of micro LEDs 2 on a native substrate, using an MTP transfer stamp to transfer the plurality of micro LEDs 2 to the substrate 1, wherein the native substrate is a sapphire-based substrate. Preferably, the plurality of micro LEDs is GaN micro LEDs, InGaN micro LEDs, or AlGaInP micro LEDs, and the substrate 1 is a glass substrate.

Specifically, the plurality of micro LEDs 2 comprises: red micro LEDs, green micro LEDs and blue micro LEDS, wherein a red micro LED, a green micro LED and a blue micro LED form a display pixel.

It should be noted that a control circuit connected to the plurality of micro LEDs 2 is disposed between the substrate 1 and the plurality of micro LEDs 2. The control circuit comprises a plurality of thin film transistors (TFT) disposed correspondingly to the plurality of micro LEDs 2. The control circuit drives the plurality of micro LEDs 2 to display images.

In summary, the present invention provides a 3D display device, which uses micro LEDs display device to display image and disposes a microlens encapsulating array layer at the light-emitting side of the micro LED display device. The microlens encapsulating array layer provides both encapsulating protection to the micro LEDs and distinguishing the left-eye and right-eye viewpoints to achieve 3D display. With the microlens encapsulating array layer, the structure of the micro LED 3D display device is simplified to achieve naked-eye 3D display, reduce production cost and improve display quality.

It should be noted that in the present disclosure the terms, such as, first, second are only for distinguishing an entity or operation from another entity or operation, and does not imply any specific relation or order between the entities or operations. Also, the terms “comprises”, “include”, and other similar variations, do not exclude the inclusion of other non-listed elements. Without further restrictions, the expression “comprises a . . . ” does not exclude other identical elements from presence besides the listed elements.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the clams of the present invention.

What is claimed is:

1. A three-dimensional (3D) display device, which comprises: a substrate, a plurality of micro LEDs disposed on the substrate and arranged in an array, a dielectric layer disposed on the plurality of micro LEDs, and a microlens encapsulating array layer disposed on the dielectric layer;
the dielectric layer being made of a transparent dielectric; and
the microlens encapsulating array layer encapsulating and protecting the micro LEDs, and refracting light emitted by the micro LEDs at different locations of the substrate to different spatial directions to form a left-eye viewpoint and a right-eye viewpoint for a viewer so as to achieve 3D display.

2. The 3D display device as claimed in claim 1, wherein the microlens encapsulating array layer is made of semiconductor material, ammonium dichromate gelatin, or resin-based material.

3. The 3D display device as claimed in claim 1, wherein the microlens encapsulating array layer is prepared by a photo-resist melting method.

4. The 3D display device as claimed in claim 1, wherein the microlens encapsulating array layer comprises: a plurality of microlens units arranged in an array, and the microlens unit has a hemispherical shape.

5. The 3D display device as claimed in claim 1, wherein the plurality of micro LEDs comprises: red micro LEDs, green micro LEDs and blue micro LEDs.

6. The 3D display device as claimed in claim 1, wherein the plurality of micro LEDs is manufactured by micro transfer printing (MTP).

7. The 3D display device as claimed in claim 1, wherein a control circuit connected to the plurality of micro LEDs is disposed between the substrate and the plurality of micro LEDs.

8. The 3D display device as claimed in claim 1, wherein the plurality of micro LEDs is GaN micro LEDs, InGaN micro LEDs, or AlGaInP micro LEDs.

9. A three-dimensional (3D) display device, which comprises: a substrate, a plurality of micro LEDs disposed on the substrate and arranged in an array, a dielectric layer disposed on the plurality of micro LEDs, and a microlens encapsulating array layer disposed on the dielectric layer;
the dielectric layer being made of a transparent dielectric; and
the microlens encapsulating array layer encapsulating and protecting the micro LEDs, and refracting light emitted by the micro LEDs at different locations of the substrate to different spatial directions to form a left-eye viewpoint and a right-eye viewpoint for a viewer so as to achieve 3D display;
wherein the microlens encapsulating array layer being made of semiconductor material, ammonium dichromate gelatin, or resin-based material; and
wherein the microlens encapsulating array layer being prepared by a photo-resist melting method.

10. The 3D display device as claimed in claim 9, wherein the microlens encapsulating array layer comprises: a plurality of microlens units arranged in an array, and the microlens unit has a hemispherical shape.

11. The 3D display device as claimed in claim 9, wherein the plurality of micro LEDs comprises: red micro LEDs, green micro LEDs and blue micro LEDs.

12. The 3D display device as claimed in claim 9, wherein the plurality of micro LEDs is manufactured by micro transfer printing (MTP).

13. The 3D display device as claimed in claim 9, wherein a control circuit connected to the plurality of micro LEDs is disposed between the substrate and the plurality of micro LEDs.

14. The 3D display device as claimed in claim 9, wherein the plurality of micro LEDs is GaN micro LEDs, InGaN micro LEDs, or AlGaInP micro LEDs.
